(19) United States
(12) Patent Application Publication
(10) Pub. No.: US 2014/0049282 A1
(43) Pub. Date: Feb. 20, 2014

(54) LENSING SYSTEM AND METHOD FOR PHOTOVOLTAIC DEVICES

(71) Applicant: Jason Stephens, Mountain View, CA (US)

(72) Inventor: Jason Stephens, Mountain View, CA (US)

(73) Assignee: ThinSilicon Corporation, Mountain View, CA (US)

(21) Appl. No.: 13/586,948

(22) Filed: Aug. 16, 2012

(51) Int. Cl. G01R 31/26; H01L 31/048; H01L 31/052

(52) U.S. Cl. 324/761.01; 136/246; 136/251

(57) ABSTRACT

A photovoltaic device includes a substrate extending between opposite edges, a plurality of photovoltaic cells electrically coupled with each other in series, wherein the plurality of photovoltaic cells includes at least one current-limiting photovoltaic cell, and at least one corrective optic lens positioned over the at least one current-limiting photovoltaic cell. The at least one corrective optic lens is configured to focus light into the at least one current-limiting photovoltaic cell so that current passing through the current-limiting photovoltaic cell is boosted. A monitoring system may include at least one light source aligned with at least one of the plurality of photovoltaic cells. The light source(s) may be configured to emit light into the at least one of the plurality of photovoltaic cells to determine if the power output of the photovoltaic device remains constant.

### BACKGROUND

Embodiments of the subject matter described herein relate to photovoltaic devices.

Various photovoltaic devices include one or more layers of a semiconductor, such as silicon. Light that is incident on the device passes into the semiconductor layer. If the light is absorbed by the semiconductor layer, the light may excite electrons from the semiconductor material of the layer. The electrons flow to one or more electrodes disposed on opposite sides of the semiconductor layer. The electrons collected at the electrodes create an electric current that may be drawn from the device and applied to an external electric load.

Within a photovoltaic device, the electrodes and the semiconductor layer may form photovoltaic cells. The photovoltaic cells are configured to convert incident light into electric current, such as by generating electron-hole pairs when the light is absorbed by the semiconductor layer The electron-hole pairs are conveyed as electric current in the electrodes. The electrodes in neighboring photovoltaic cells are conductively coupled with each other through gaps in the semiconductor layer. The conductive coupling of the photovoltaic cells causes them to be electrically connected in series so that the electric current, or voltage, generated in the cells is additive. For example, as the number of photovoltaic cells increases, the total current generated by the photovoltaic device increases. Thus, if one of the cells is malfunctioning or otherwise defective, the total current generated by the photovoltaic device is affected. However, a simple replacement of a defective current-limiting cell may not be possible. That is, because the cells are connected in series, if one of the cells is removed, the entire photovoltaic device may be rendered inoperable. Moreover, even if the cell can be replaced, the cost of replacing the particular cell and connecting it to the other cells may be greater than simply manufacturing a new photovoltaic device.

Additionally, due to variances in the manufacturing processes involved in creating photovoltaic devices, not all cells may be identical. For example, systematic differences in the quality of semiconductor layers (e.g., differences in layer thickness and/or material properties in the layers) in the devices due to imperfections in deposition equipment may result in some cells producing less current than others.

### BRIEF DESCRIPTION OF THE INVENTION

Certain embodiments provide a photovoltaic device including a substrate, a plurality of photovoltaic cells, and at least one corrective optic lens. The substrate extends between opposite edges. The plurality of photovoltaic cells electrically couple with each other in series. At least one of the plurality of photovoltaic cells is a current-limiting photovoltaic cell. The at least one corrective optic lens is positioned over the at least one current-limiting photovoltaic cell. The at least one corrective optic lens is configured to focus light into the at least one current-limiting photovoltaic cell so that current generated by the current-limiting photovoltaic cell is boosted.

The device may also include an adhesive layer positioned over the plurality of photovoltaic cells, and a protective cover positioned over the adhesive layer. The at least one corrective optic lens may be positioned within the adhesive layer (such as during fabrication of the device). Alternatively, the at least one corrective optic lens may be positioned over the protective cover (such as after the device is fabricated).

The at least one corrective optic lens may include first and second corrective optic lenses positioned over first and second current-limiting cells, respectively. The first corrective optic lenses may focus a different amount of light into the first current-limiting cell than the second corrective optic lens focuses into the second current-limiting cell.

The at least one corrective optic lens may include a converging corrective optic lens having a middle section thicker than outer edges. The converging corrective optic lens may be configured to focus light energy into a focal surface, plant, or point within the at least one current-limiting cell. Alternatively, the at least one corrective optic lens may include a diverging corrective optic lens having outer edges that are thicker than a middle section. In this case, the diverging corrective optic lens may spread light uniformly through the at least one current-limiting cell.

The at least one corrective lens may extend from a planar lens layer of refractive material.

A monitoring system may include at least one light source aligned with at least one of the plurality of photovoltaic cells. The at least one light source may be configured to emit light into the at least one of the plurality of photovoltaic cells to determine if the power output of the photovoltaic device remains constant.

Certain embodiments provide a system for monitoring and testing a plurality of photovoltaic cells of a photovoltaic device. The system may include a housing configured to be removably positioned on a surface of the photovoltaic device, and at least one light source within the housing. The at least one light source may be configured to be aligned with at least one of the plurality of photovoltaic cells when the housing is positioned on the surface of the photovoltaic device. The at least one light source may be configured to selectively emit light into the at least one photovoltaic cell to determine if the photovoltaic cell is current-limiting.

The at least one light source may include a plurality of light sources aligned with at least a portion of the plurality of photovoltaic cells. The number of the plurality of light sources may equal the number of the plurality of photovoltaic cells.

The system may also include a control unit operatively connected to the housing. The control unit may be configured to allow a user to selectively activate and deactivate the at least one light source.

The system may also include a processing device in communication with the photovoltaic device. The processing device may determine that the at least one photovoltaic cell is current-limiting if a power output of the photovoltaic device increases when the at least one light source emits light into the at least one photovoltaic cell.

Certain embodiments provide a method of identifying a current-limiting photovoltaic cell within a photovoltaic device. The method may include positioning a housing of a monitoring system on a surface of the photovoltaic device, wherein the housing includes at least one light source. The method may also include aligning the at least one light source of the housing with at least one photovoltaic cell, activating the at least one light source of the housing to emit light into the at least one photovoltaic cell, monitoring the power output of the photovoltaic device before and during the activating, determining that the at least one photovoltaic cell is properly functioning if the power output of the photovoltaic device remains constant during the monitoring, and determining that the at least one photovoltaic cell is current-limiting if the power output of the photovoltaic device changes during the monitoring.

In an embodiment, the power output of the photovoltaic device increases during the determining if the at least one photovoltaic cell is current-limiting.

The method may also include positioning a corrective optical lens over each of the plurality of photovoltaic devices that has been determined to be current-limiting.

The activating may include varying the intensity of emitted light from the at least one light source.

### BRIEF DESCRIPTION OF THE DRAWINGS

FIG. 1 illustrates a schematic view of a photovoltaic device and a lensing system, according to an embodiment.

FIG. 2 illustrates a cross-sectional view of a photovoltaic device along line A-A of FIG. 1, according to an embodiment.

FIG. 3 illustrates a cross-sectional view of a corrective optical lens, according to an embodiment.

FIG. 4 illustrates a cross-sectional view of a photovoltaic device along line A-A of FIG. 1, according to an embodiment.

FIG. 5 illustrates a cross-sectional view of a photovoltaic device along line A-A of FIG. 1, according to an embodiment.

FIG. 6 illustrates a cross-sectional view of a photovoltaic device along line A-A of FIG. 1, according to an embodiment.

FIG. 7 illustrates a cross-sectional view of a photovoltaic device along line A-A of FIG. 1, according to an embodiment.

FIG. 8 illustrates a schematic of a system for monitoring a photovoltaic device of FIG. 1, according to an embodiment.

FIG. 9 illustrates a flow chart of a method of monitoring and testing a photovoltaic device, according to an embodiment.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings. Moreover, it should be understood that the components in the drawings are not to scale and the relative sizes of one component to another should not be construed or interpreted to require such relative sizes.

### DETAILED DESCRIPTION

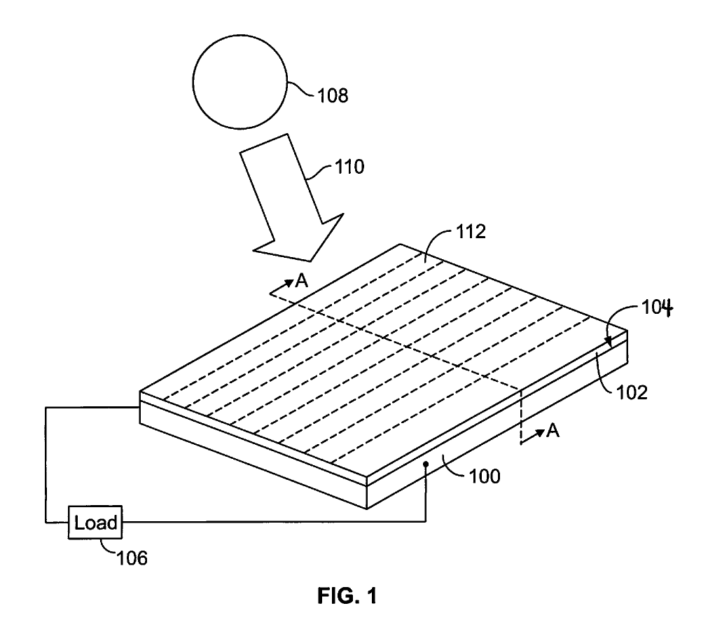

FIG. 1 illustrates a schematic view of a photovoltaic device 100 and a lensing system 102, according to an embodiment. The photovoltaic device 100 receives light 110 from an external light source 108 (for example, the sun, an artificial light, or the like) through an upper light receiving surface 104 and converts the light into electric current. The photovoltaic device 100 is conductively coupled with one or more electric loads 106 (“Load” in FIG. 1). Electric current generated by the photovoltaic device 100 is supplied to the electric load 106, which may be any electric device that is powered by the current or a power storage device, such as a battery.

The photovoltaic device 100 includes a plurality of photovoltaic cells 112 that are conductively coupled with each other, such as by being coupled in series with each other. The photovoltaic cells 112 are shown in FIG. 1 as being elongated with side boundaries of the photovoltaic cells 112 defined by dashed lines. Alternatively, the photovoltaic cells 112 may have different shapes, such as circles, squares, or other shapes. The photovoltaic cells 112 may each convert incident light 110 into the electric current for the load 106. The photovoltaic cells 112 can be conductively coupled in series so that the currents generated by the photovoltaic cells 112 are additive and produce a greater output current from the photovoltaic device 100 than the current generated individually by one of the photovoltaic cells 112. The number and/or arrangement of the photovoltaic cells 112 are provided merely as examples and are not intended to be limiting on all embodiments of the presently described subject matter.

The different photovoltaic cells 112 may produce or output different amounts of electric current when the light 110 is received by the photovoltaic cells 112. The amount of current generated or efficiency of a photovoltaic cell 112 in converting incident light into electric current may be represented by one or more conversion characteristics of the photovoltaic cells 112. The conversion characteristics may include short circuit current densities or photocurrent densities (Jsc), current-voltage (I-V) curves or relationships, and/or external quantum efficiencies (EQE) of the photovoltaic cells 112.

The lensing system 102 is disposed between the light source 108 and the photovoltaic device 100. The lensing system 102 focuses at least some of the light 110 toward one or more of the photovoltaic cells 112. For example, the lensing system 102 may include one or more lenses that refract the light 110 such that more light is directed into or toward one or more photovoltaic cells 112 than is directed into or toward one or more other photovoltaic cells 112 of the same photovoltaic device 100. By directing more light 110 into some photovoltaic cells 112 as compared to other photovoltaic cells 112, the lensing system 102 may cause less light 110 to be received by the other photovoltaic cells 112.

In one embodiment, the lensing system 102 may change how the incident light 110 is received into the photovoltaic device 100 based on the conversion characteristics of the photovoltaic cells 112. For example, the lensing system 102 may direct more light 110 into one or more of the photovoltaic cells 112 that produce less electric current than one or more other photovoltaic cells 112 when the same or approximately the same intensity of light 110 is incident on the photovoltaic cells 112. Different photovoltaic cells 112 in the same photovoltaic device 100 may have different conversion characteristics and, as a result, may have different conversion efficiencies in converting incident light 110 into electric current. The amount of current generated by a photovoltaic cell 112 may be based on the amount or intensity of the light 110 received by the photovoltaic cell 112. The amount or intensity of the light 110 may be measured or represented in various units, including joules or watts (e.g., for radiant energy or flux), watts per meter (e.g., for spectral power), and the like. By increasing the amount or intensity of the light 110 that is received by the photovoltaic cell or cells 112 having lower conversion characteristics (e.g., lower conversion efficiencies), the lensing system 102 may increase the amount of current that is generated by the photovoltaic cell or cells 112 having the lower conversion characteristics. As a result, the total output of electric current from the photovoltaic device 100 may increase.

The lensing system 102 may include one or more light transmissive bodies (e.g., transparent to one or more wavelengths of light 110 and/or permitting more light 110 to pass through the bodies than is blocked) that refract portions of the light 110 toward selected photovoltaic cells 112 in the photovoltaic device 100. The bodies may represent or be lenses or parts of lenses that converge at least some of the light 110 toward the selected photovoltaic cell or cells 112. The bodies may be single or compound lenses, such as one or more biconvex, plano-convex, positive meniscus, negative meniscus, plano-concave, and/or biconcave lenses. In one embodiment, the lensing system 102 may be disposed outside the photovoltaic device 100, such as by adhering the lensing system 102 onto an external or light-receiving surface of the photovoltaic device 100, such as on the cover glass of the photovoltaic device 100.

In another embodiment, the lensing system 102 may be disposed inside the photovoltaic device 100. For example, the lensing system 102 may be disposed beneath a cover glass or other external protective body of the lensing system 102. In such an embodiment, the lensing system 102 may not be visible on the external side of the photovoltaic device 100 as shown in FIG. 1.

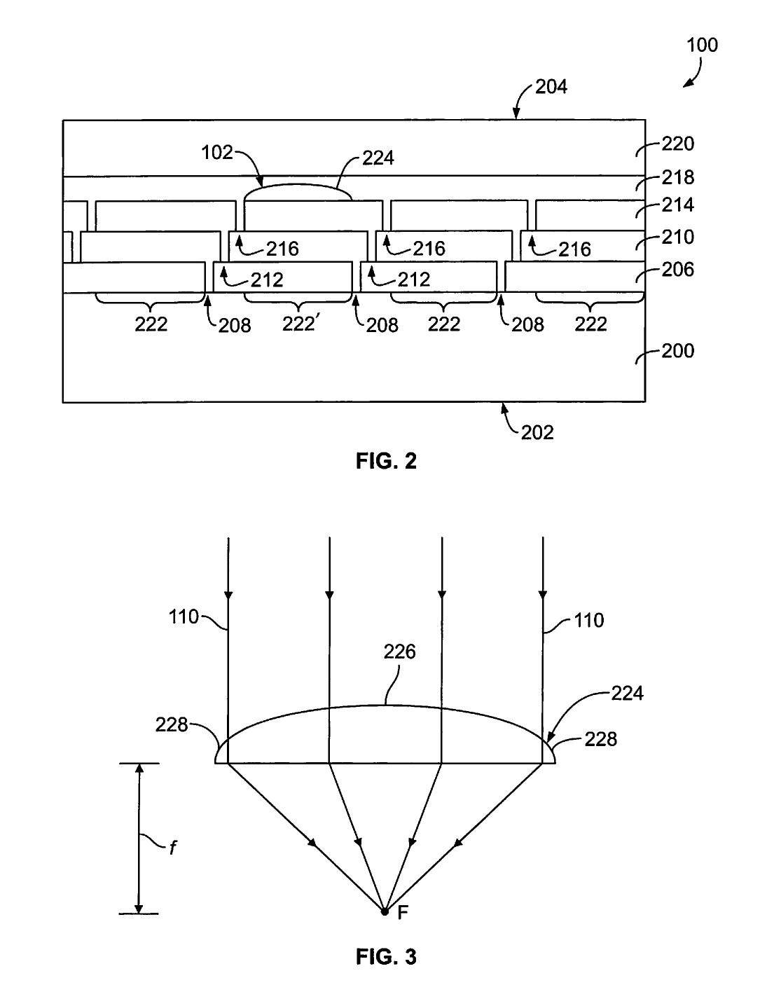

FIG. 2 illustrates a cross-sectional view of the photovoltaic device 100 along line A-A of FIG. 1, according to an embodiment. The photovoltaic device 100 includes a substrate 200 that extends along a base or first side 202 of the photovoltaic device 100 that is opposite a second, or light-receiving, surface or side 204 of the photovoltaic device 100. The substrate 200 may be a conductive or non-conductive body that mechanically supports the additional components of the photovoltaic device 100. In one embodiment, the photovoltaic device 100 receives light through the second side 204 to convert the light into electric current. Alternatively, the light may be received through the first side 202 (e.g., with the substrate 200 formed from one or more light transmissive materials) to convert the light into electric current.

A conductive first electrode 206 is disposed between the substrate 200 and the second side 204 of the photovoltaic device 100. As shown in FIG. 2, the first electrode 206 may be separated into plural portions by gaps 208. The gaps 208 may extend along the length of the photovoltaic device 100 such that each portion of the first electrode 206 is spatially separated from the neighboring portions of the first electrode 206.

A semiconductor layer 210 is disposed between the first electrode 206 and the second side 204 of the photovoltaic device 100. The semiconductor layer 210 is formed from one or more layers or sub-layers of semiconductor material. The semiconductor layer 210 may include one or more junctions, such as an NIP junction (formed from n-doped, intrinsic, and p-doped layers) and/or a PIN junction (formed from p-doped, intrinsic, and n-doped layers). Similar to the first electrode 206, the semiconductor layer 210 may be separated into plural portions by gaps 212. The gaps 212 may extend along the length of the photovoltaic device 100 such that each portion of the semiconductor layer 210 is spatially separated from the neighboring portions of the semiconductor layer 210.

A conductive second electrode 214 is disposed between the semiconductor layer 210 and the second side 204 of the photovoltaic device 100. The second electrode 214 also may be separated into plural portions by gaps 216. The gaps 216 may extend along the length of the photovoltaic device 100 such that each portion of the second electrode 214 is spatially separated from the neighboring portions of the second electrode 214. In one embodiment, the second electrode 214 is formed from light transmissive materials that allow one or more wavelengths of light to pass through the second electrode 214. Alternatively, the second electrode 214 may be opaque or reflective to light and the first electrode 206 may be formed from light transmissive materials.

An adhesive layer 218 is disposed between the second electrode 214 and the second side 204 of the photovoltaic device 100. The adhesive layer 218 may secure a protective cover 220 to the photovoltaic device 100. In one embodiment, the cover 220 and adhesive 218 may be formed from light transmissive materials that allow light to enter through the second side 204 of the photovoltaic device 100.

As shown in FIG. 2, the portions of the electrodes 206, 214 and semiconductor layer 210 form photovoltaic cells 222 of the photovoltaic device 100. The photovoltaic cells 222 convert incident light into electric current, such as by generating electron-hole pairs when the light is absorbed by the semiconductor layer 210. The electron-hole pairs are conveyed as electric current in the electrodes 206, 214. In the illustrated embodiment, the electrodes 206, 214 in neighboring photovoltaic cells 100 are conductively coupled with each other through the gaps 212 in the semiconductor layer 210. The conductive coupling of the photovoltaic cells 222 causes the cells 222 to be electrically connected in series so that the electric current, or voltage, generated in the cells 222 is additive. For example, as the number of photovoltaic cells 222 increases, the total current generated by the photovoltaic device 100 increases. The outermost cells 222 (or one or more other cells) may be conductively coupled with leads or wires that extend to the load 108 (shown in FIG. 1).

In an embodiment, the lensing system 102 includes a corrective optical lens 224 that is oriented over a current-limiting cell 222′ of the photovoltaic device 100. The corrective optical lens 224 shown in FIG. 2 may be referred to as an internal corrective optical lens or internal lensing system in that the corrective optical lens 224 is disposed inside the photovoltaic cell 100 within the adhesive layer 218 between the cover 220 and the second electrode 214. The current-limiting cell 222′ may represent a cell 222′ that produces less current (such as voltage) than other cells 222 in the same photovoltaic device 100 when the cells 222 of the photovoltaic device 100 are exposed to the same amount or intensity of light. The corrective optical lens 224 may refract incident light that is received through the second side 204 of the photovoltaic cell 100 so as to increase the amount or intensity of the light that is received in the current-limiting cell 222′ relative to one or more, or all, of the other cells 222. Increasing the amount of light received by the current-limiting cell 222′ relative to the other, non-current-limiting cells 222 may increase the amount of current that is generated by the current-limiting cell 222′ such that the current-limiting cell 222′ does not increase the total current or power generated by the photovoltaic device 100.

FIG. 3 illustrates a cross-sectional view of the corrective optical lens 224, according to an embodiment. The corrective optical lens 224 may be a converging lens having a middle section 226 that is thicker than outer edges 228. As shown in FIG. 3, the thickness of the corrective optical lens 224 may steadily decrease toward the outer edges 228. Accordingly, the corrective optical lens 224 may have a positive focal length f. Rays of light 110 from an external source pass through the corrective optical lens 224, are converged by the corrective optical lens 224, and focused at focal point F, which is the focal length f away from the corrective optical lens 224. In this manner, the rays of light 110 may be focused into current limiting cells 222′. Again, the corrective optical lens 224 may be a converging lens that brings together, or converges, parallel rays of light 110. Alternatively, the corrective optical lens 224 may be a diverging lens having a middle section that is thinner than outer edges, and therefore diverges, or spreads light apart, into the current-limiting cell 222′. In this manner, the diverging lens may provide uniform light distribution into the current-limiting cell 222′, as opposed to focusing light onto a single point within the current-limiting cell 222′. While specific examples are described above, in general, lenses may modify spatially-uniform incoming light to have different or non-uniform intensity patterns.

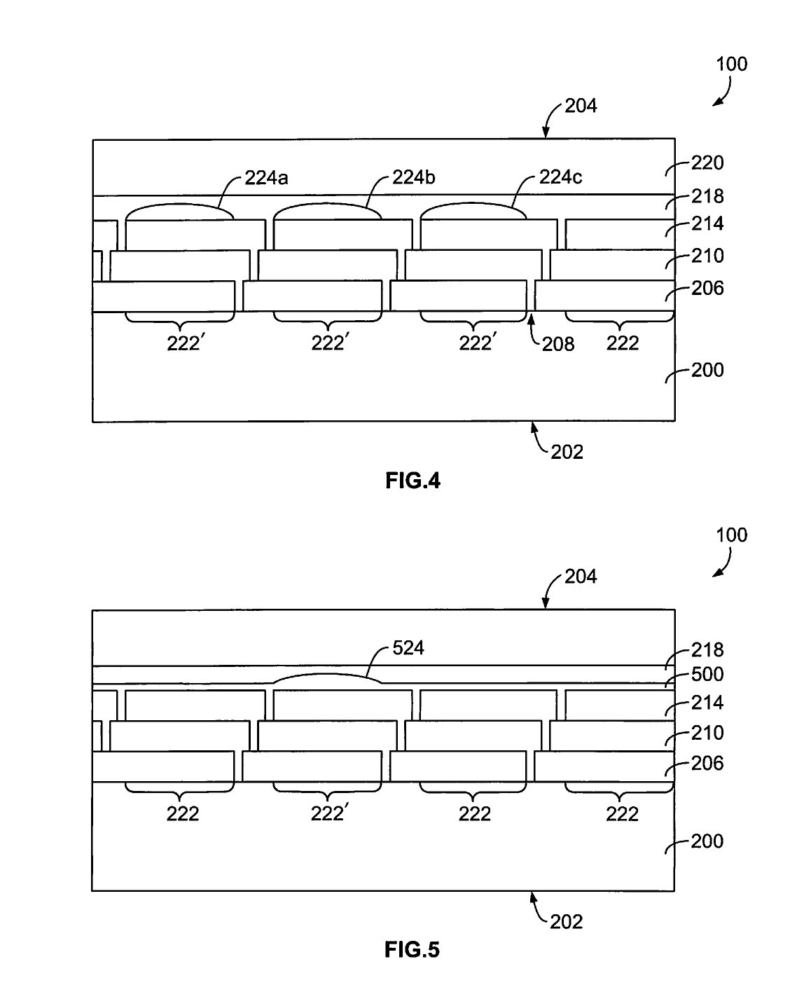

FIG. 4 illustrates a cross-sectional view of the photovoltaic device 100 along line A-A of FIG. 1, according to an embodiment. In this embodiment, three of the cells 222 are current-limiting cells 222′. Accordingly, a corrective optical lens 224 is oriented over each current-limiting cell 222′, as discussed above. More or less corrective optical lenses 224 may be used, depending on the number of current-limiting cells 222′. For example, if the photovoltaic device 100 has six current-limiting cells 222′, six corrective optical lenses 224 may be used, such that one corrective optical lens 224 is oriented over each current-limiting cell 222′.

Additionally, each corrective optical lens 224a, 224b, and 224c may focus different amounts of light into the current-limiting cells 222′. Depending on the level of current limit of each current-limiting cell 222′, the lenses 224a, 224b, and 224c may focus varying degrees of light so that the current output of each cell 222′ and 222 is uniform. For example, if the current-limiting cell 222′ under which the lens 224a is positioned is the weakest, the lens 224a may direct more light into the current-limiting cell 222′ as compared to the lenses 224b and 224c and their respective cells 222′.

FIG. 5 illustrates a cross-sectional view of the photovoltaic device 100 along line A-A of FIG. 1, according to an embodiment. In this embodiment, the lensing system includes a lens layer 500 is formed within the same plane as the adhesive layer 218, under the cover 220, but above the photovoltaic cells 222. The lens layer 500 is formed of a light-refracting material and includes a corrective optical lens 524 over a current-limiting cell 222′. Thus, the lens layer 500 may be a planar sheet of refractive material within the photovoltaic device 100 with an expanded bump, protrusion, or the like formed over the current-limiting cell 222′. The bump, protrusion, or the like formed within the photovoltaic device 100 defines the corrective optical lens 524. Depending on the number of current-limiting cells 222′ within the photovoltaic device 100, a number of bumps, protrusions, or the like may be formed over the current-limiting cells 222′. As such, the lens layer 500 may include more corrective optical lenses 524 than shown in FIG. 5. Further, each corrective optical lens 524 may direct different degrees of light energy into the respective current-limiting cells.

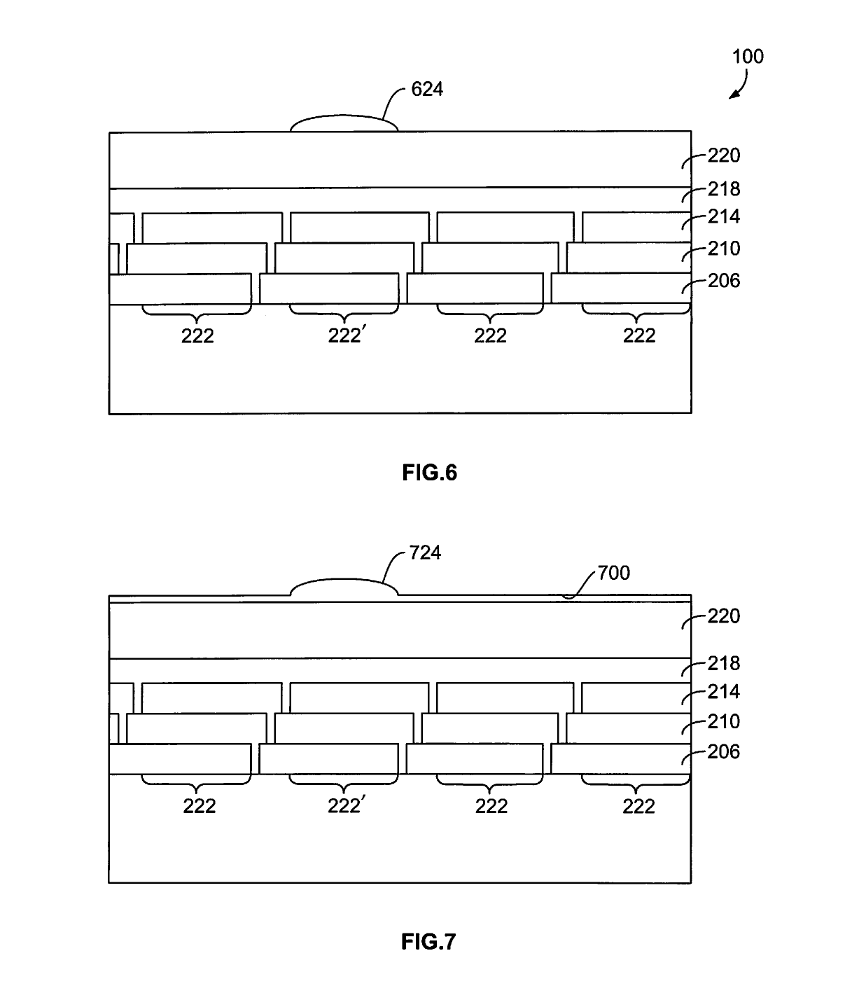

FIG. 6 illustrates a cross-sectional view of the photovoltaic device 100 along line A-A of FIG. 1, according to an embodiment. It may be discovered that a photovoltaic cell is current-limiting after fabrication of the device 100. In this scenario, removing the protective cover 220 would degrade the device 100 or possibly render it inoperable. Therefore, in order to rectify the current-limiting cell 222′, the lensing system may include a corrective optical lens 624 that may be secured on the protective cover 220 over the current-limiting cell 222′. Additionally lenses 624 may be secured on the cover 220 over additional current-limiting cells as they are discovered. Further, as described above, each lens 624 may focus light energy at different levels, depending on the current limit of each current-limiting cell.

FIG. 7 illustrates a cross-sectional view of the photovoltaic device 100 along line A-A of FIG. 1, according to an embodiment. If a current-limiting cell 222′ is discovered after fabrication of the device 100, a lens layer 700 formed of refractive material may be deposited, formed, or otherwise positioned over the protective cover 220. The lens layer 700 may include a formed corrective optical lens 724 over the current-limiting cell 222′. As discussed above, more corrective optical lenses 724 may be formed if additional current-limiting cells are discovered.

Referring to FIGS. 1-7, each corrective optical lens may be custom-designed to accommodate each particular current-limiting cell. For example, if a particular current-limiting cell limits current by a certain factor, the corrective optical lens may be custom-designed to generate a particular light intensity pattern in order to correct for the particular current-limiting factor.

In other embodiments, a single corrective optical lens may be used for all current-limiting cells. The single corrective optical lens may be designed to compensate for systematic differences in film quality (such as thickness or variations in material properties) due to imperfections in the equipment that is used to deposit the films on and into the photovoltaic device. For example, it may prove difficult to deposit microcrystalline silicon from Plasma Enhanced Chemical Vapor Deposition (PECVD) reactors with uniform properties over an entire edge-to-edge surface of a glass substrate. Often, many iterations in expensive components of the PECVD reactor are used to reduce the non-uniformity to acceptable levels. Even after the corrective process, however, if silicon layers are changed, the non-uniformity may be exacerbated. Another example of non-uniformity arises when a PECVD process is changed from a standard 13.56 MHz RF source/generator to very high frequency (VHF) or ultra-high frequency (UHF) (such as 27-54 MHz). When using higher frequency, the rate of silicon deposition is increased, thereby reducing the number of expensive PECCVD systems used during a fabrication process. However, with higher frequency, a standing-wave effect may result that generates nodes in the plasma conditions that may decrease the silicon deposition rate and change its properties. In both non-uniformity circumstances, the silicon non-uniformity may be predictable and result in known differences for photovoltaic cells. Thus, a single corrective optical lens may be used that corrects for such predictable non-uniformity.

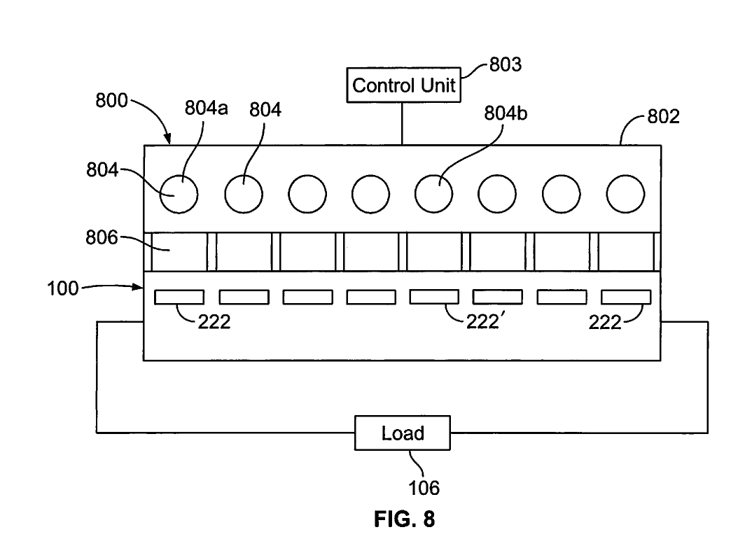

FIG. 8 illustrates a schematic of a system 800 for monitoring the photovoltaic device 100 of FIG. 1, according to an embodiment. The system 800 may be used to monitor the photovoltaic device 100 in the field. The system 800 includes a housing 802 that may be temporarily positioned on the photovoltaic device 100. The housing 802 is operatively connected to a control unit 803, which may include a processing unit, computer, or the like. The control unit 803 may include a user interface having switches and the like that allow a user to operate the system 800.

The housing 802 may include a plurality of artificial light sources 804 that may be selectively activated and deactivated. Each light source 804 connects to a light path 806 that is positioned above a photovoltaic cell 222 of the device 100. That is, the housing 802 may be configured such that the number of light sources 804 equals the number of photovoltaic cells 22 within the device 100. Optionally, the housing 802 may include less light sources 802 than the total number of cells 222. For example, the housing 804 may include only one light source 804 connected to a light path 806. The housing 802 may then be positioned over a cell 222 for testing. Once the test is complete, the housing 802 would be removed and positioned over a neighboring cell 222, and so on.

In operation, the housing 802 is positioned on the photovoltaic device 100 so that the light sources 804 and light paths 806 are aligned with respect to the cells 222. That is, the housing 802 is positioned on the device 100 such that the light sources 804 may emit light energy into the cells 222. An operator may control light emission of the light sources through the control unit 803. For example, the operator may selectively activate a light source 804a to emit light into an aligned cell 222.

Each light source 804 may have individually tunable intensities. As light is emitted into the cell 222, the control unit 803 or the load 106 monitors the power output of the device 100. The power output of the device 100 is measured as the light intensity from the light sources 804 is increased one at a time for each cell. If the power output of the device 100 remains constant as each light source 804 is activated (and with intensity possibly being varied), then all of the cells 222 are functioning properly. However, if the power output changes when one of the light sources 804, such as light source 804b is activated (and its intensity possibly increased), then the respective cell 222′ is current-limiting. Therefore, the system 800 is able to provide data as to defective cells 222′. Once a defective cell is identified through the system 800, an optic lens may be fashioned and positioned on the device 100, as shown in FIG. 6 or 7, to direct more light into the defective cell 222′. The process could then be repeated iteratively.

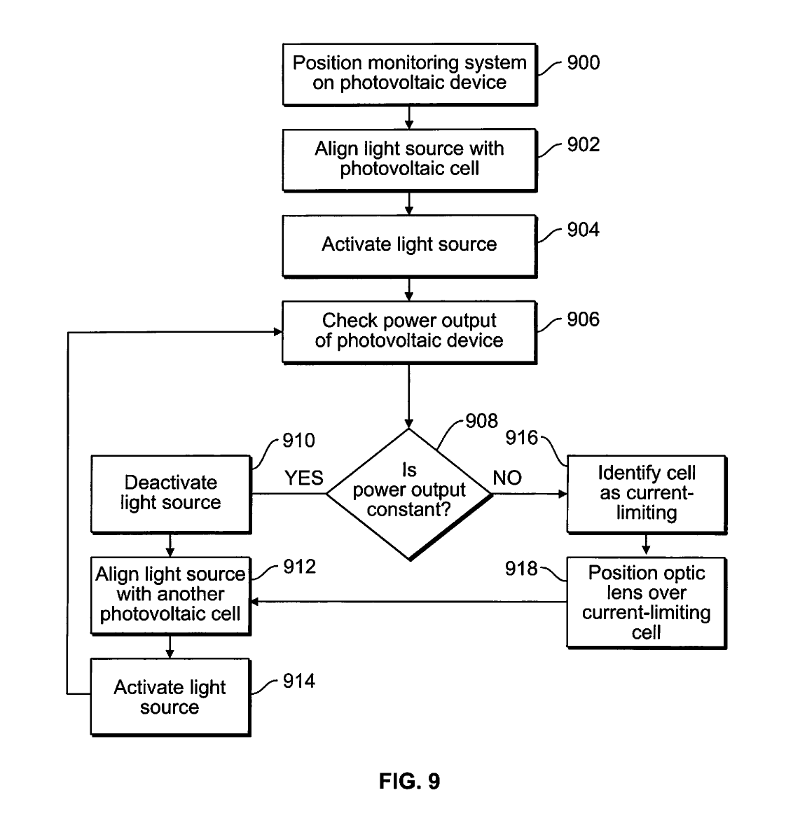

FIG. 9 illustrates a method of monitoring and testing a photovoltaic device, according to an embodiment. At 900, a monitoring system, such as the system 800 shown in FIG. 8, is positioned on the photovoltaic device. At 902, a light source is aligned with a photovoltaic cell. In an embodiment, the system may include a plurality of light sources that align with a plurality of photovoltaic cells of the photovoltaic device. Alternatively, the system may include one light source that may be aligned and removed from positions over each photovoltaic cell. At 904, the light source, which is aligned with the photovoltaic cell, is activated.

At 906, the power output of the photovoltaic device is checked and analyzed. At 908, it is determined whether the power output of the photovoltaic device is constant. If the output is constant, then at 910, the light source is deactivated. At 912, the light source (or another light source) is aligned with another photovoltaic cell. Then, at 914, that light source is activated, and the process returns to 906.

If, however, the output is not constant, then, at 916, the cell over which the light source is positioned is identified as current-limiting or otherwise defective. Consequently, at 918, an optic lens may be positioned over the current-limiting cell in order to focus more light therein and boost the current generated by the current-limiting cell.

Thus, embodiments provide a system and method for boosting the current generated by current-limiting photovoltaic cells within a photovoltaic device. Embodiments provide one more optic lenses that focus light energy into current-limiting cells to ensure consistent power output from a photovoltaic device. Embodiments also provide a system and method of monitoring and testing a photovoltaic device that identifies current-limiting cells.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter described herein without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the subject matter disclosed herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A photovoltaic device comprising:
a substrate extending between opposite edges;
a plurality of photovoltaic cells electrically coupled with each other in series, wherein the plurality of photovoltaic cells includes at least one current-limiting photovoltaic cell; and
at least one corrective optic lens positioned over the at least one current-limiting photovoltaic cell, wherein the at least one corrective optic lens is configured to focus light into the at least one current-limiting photovoltaic cell so that current generated by the current-limiting photovoltaic cell is boosted.

2. The photovoltaic device of claim 1, further comprising:
an adhesive layer positioned over the plurality of photovoltaic cells; and
a protective cover positioned over the adhesive layer.

3. The photovoltaic device of claim 2, wherein at least one corrective optic lens is positioned within the adhesive layer.

4. The photovoltaic device of claim 2, wherein the at least one corrective optic lens is positioned over the protective cover.

5. The photovoltaic device of claim 1, wherein the at least one corrective optic lens comprises first and second corrective optic lenses positioned over first and second current-limiting cells, respectively, and wherein the first corrective optic lenses focuses a different amount of light into the first current-limiting cell than the second corrective optic lens focuses into the second current-limiting cell.

6. The photovoltaic device of claim 1, wherein the at least one corrective optic lens comprises a converging corrective optic lens having a middle section thicker than outer edges, wherein the converging corrective optic lens is configured to focus light energy into a focal point within the at least one current-limiting cell.

7. The photovoltaic device of claim 1, wherein the at least one corrective optic lens comprises a diverging corrective optic lens having outer edges that are thicker than a middle section, wherein the diverging corrective optic lens spreads light uniformly through the at least one current-limiting cell.

8. The photovoltaic device of claim 1, wherein the at least one corrective lens extends from a planar lens layer of refractive material.

9. The photovoltaic device, further comprising a monitoring system including at least one light source aligned with at least one of the plurality of photovoltaic cells, wherein the at least one light source is configured to emit light into the at least one of the plurality of photovoltaic cells to determine if the power output of the photovoltaic device remains constant.

10. A system for monitoring and testing a plurality of photovoltaic cells of a photovoltaic device, the system comprising:
a housing configured to be removably positioned on a surface of the photovoltaic device; and
at least one light source within the housing, wherein the at least one light source is configured to be aligned with at least one of the plurality of photovoltaic cells when the housing is positioned on the surface of the photovoltaic device, and wherein the at least one light source is configured to selectively emit light into the at least one photovoltaic cell to determine if the photovoltaic cell is current-limiting.

11. The system of claim 10, wherein the at least one light source comprises a plurality of light sources aligned with at least a portion of the plurality of photovoltaic cells.

12. The system of claim 10, wherein the number of the plurality of light sources equals the number of the plurality of photovoltaic cells.

13. The system of claim 10, further comprising a control unit operatively connected to the housing, wherein the control unit is configured to allow a user to selectively activate and deactivate the at least one light source.

14. The system of claim 10, further comprising a processing device in communication with the photovoltaic device, wherein the processing device determines that the at least one photovoltaic cell is current-limiting if a power output of the photovoltaic device increases when the at least one light source emits light into the at least one photovoltaic cell.

15. A method of identifying a current-limiting photovoltaic cell within a photovoltaic device, the method comprising:
positioning a housing of a monitoring system on a surface of the photovoltaic device, wherein the housing comprises at least one light source;
aligning the at least one light source of the housing with at least one photovoltaic cell;
activating the at least one light source to the housing to emit light into the at least one photovoltaic cell;
monitoring a power output of the photovoltaic device before and during the activating;
determining that the at least one photovoltaic cell is properly functioning if the power output of the photovoltaic device remains constant during the monitoring; and
determining that the at least one photovoltaic cell is current-limiting if the power output of the photovoltaic device changes during the monitoring.

16. The method of claim 15, wherein the power output of the photovoltaic device increases during the determining if the at least one photovoltaic cell is current-limiting.

17. The method of claim 15, wherein the at least one light source comprises a plurality of light sources and the at least one photovoltaic cell comprises a plurality of photovoltaic cells, and wherein the aligning comprises aligning the plurality of light sources over at least a portion of the plurality of photovoltaic devices.

18. The method of claim 17, wherein the number of the plurality of light sources equals the number of photovoltaic devices.

19. The method of claim 15, further comprising positioning a corrective optical lens over each of the plurality of photovoltaic devices that has been determined to be current-limiting.

20. The method of claim 10, wherein the activating comprises varying the intensity of emitted light from the at least one light source.
